(19) United States
(12) Patent Application Publication
(10) Pub. No.: US 2023/0307518 A1
(43) Pub. Date: Sep. 28, 2023

(54) Hetero-Junction Bipolar Transistor and Method of Manufacturing the Same

(71) Applicant: Nippon Telegraph and Telephone Corporation, Tokyo (JP)

(72) Inventor: Yuta Shiratori, Musashino-shi, Tokyo (JP)

(21) Appl. No.: 18/041,255

(22) PCT Filed: Sep. 7, 2020
(86) PCT No.: PCT/JP2020/033722

§ 371 Date: Feb. 10, 2023

(51) Int. Cl. H01L 29/423; H01L 29/08; H01L 29/417; H01L 29/66; H01L 29/737; H01L 29/10

(52) U.S. Cl. CPC H01L 29/42304; H01L 29/0821; H01L 29/41708; H01L 29/66318; H01L 29/737; H01L 29/1004

(57) ABSTRACT

A HBT includes a collector electrode, a sub-collector layer, a collector layer, a base layer, an emitter layer, an emitter cap layer, an emitter electrode, and a base electrode on a substrate, and the base pad electrode is electrically connected to the base electrode and is formed to extend outward from the base layer in a plan view, and a support portion supports an extension part of the base pad electrode on the collector electrode.

### TECHNICAL FIELD

The present invention relates to a hetero-junction bipolar transistor and a method for manufacturing the same.

### BACKGROUND ART

An indium-phosphorus (InP)-based hetero-junction bipolar transistor (HBT) is a transistor with excellent high-speed characteristics that is suitable for integrated circuits for optical/radio communication. In order to achieve a further increase in speed of the InP-based HBT, it is important to reduce an intrinsic capacitance and a parasitic capacitance and shorten charging and discharging times by miniaturizing an element, while maintaining an amount of operating current. On the other hand, since the thermal resistance of the element increases due to the miniaturization, a junction temperature of the element (an internal temperature of the element) increases due to the miniaturization. Since the junction temperature is a factor that greatly affects not only direct electrical characteristics such as an electron velocity and a current gain but also long-term reliability, heat dissipation measures are essential when increasing the HBT speed.

For improving the heat dissipation of the HBT, there is a technique disclosed in, for example, NPL 1. A HBT as shown in FIG. 3 is disclosed in NPL 1. The HBT includes a metal layer 302 formed on a heat dissipation substrate 301, a sub-collector layer 303, a collector layer 304, a base layer 305, an emitter layer 306 and an emitter cap layer 307 formed on the metal layer 302. An emitter electrode 308 is formed on the emitter cap layer 307, and a base electrode 309 is formed on the base layer 305 around the emitter layer 306. The metal layer 302 functions as a collector electrode.

In the HBT having the above-described configuration, according to the technique of NPL 1, a part of the base electrode 309 forms a so-called base pad structure formed in a wider area to be connected to an upper layer wiring (not shown).

Heat generated in the HBT is generally radiated from the collector layer 304 toward the heat dissipation substrate 301 by heat conduction in a solid body. According to the above structure, because the layer (metal layer 302) on the side closer to the heat dissipation substrate 301 is made of a material having a higher thermal conductivity than a compound semiconductor constituting the emitter layer 306, the base layer 305, the collector layer 304, and the sub-collector layer 303, heat dissipation of the HBT can be improved.

However, in the structure of NPL 1, because it is difficult to reduce the collector parasitic capacitance generated between the base electrode 309 of the base pad structure and the metal layer 302 serving as the collector electrode with high accuracy, there is a new problem in that a restriction is generated in the acceleration. A detailed description will be given below.

In general, two methods for reducing parasitic capacitance of a base pad structure are conceivable. A first method is to reduce an area of the base pad structure, and a second method is to remove a semiconductor layer (the base layer, the collector layer, and the sub-collector layer) that exists between the base electrode and the collector electrode of the base pad structure.

In general, in the base pad structure, in a case where an exposure technique used when manufacturing a hetero-junction bipolar transistor of an emitter width of 0.25 m is used, when considering contact position accuracy between the upper layer wiring and the base pad electrode and a dimensional variation of the contact hole, an area of about 1 m² is typically required. For this reason, significant reduction in size of the base pad structure by the first method may cause different problems such as poor connection and short circuiting between terminals.

In principle, it is possible to reduce the size of the base pad structure simply by using a high-resolution exposure technique in the process of connecting the base pad structure and the upper wiring. However, introduction of a high-resolution exposure apparatus for a first process leads to an increase in the process cost. Therefore, it is needless to say that a base pad structure having an area which can be connected to the upper layer wiring with a high yield is desirable in the exposure technique equivalent to that of the element forming process.

In order to remove the semiconductor layer (base layer, collector layer, and sub-collector layer) directly under the base pad structure mentioned as the second method, typically, a method of removing by wet etching using a chemical solution corresponding to the material of the base layer, the collector layer, and the sub-collector layer is adopted. However, in wet etching, an amount of etching per hour is greatly affected by etching conditions such as a temperature and concentration of the chemical solution, an area and density of the surface to be etched, and a crystal orientation. Therefore, for example, in regions having different transistor densities in the wafer surface, the side etching amount of the semiconductor layer directly under the base pad structure varies, which may cause a variation in the parasitic collector capacitance of the transistor in the wafer surface.

If the side etching amount is insufficient, the parasitic collector capacitance cannot be significantly reduced. On the other hand, when the semiconductor layer directly under the base pad electrode is excessively side-etched, a base pad electrode end is deflected to the substrate side by the self-weight of the base pad electrode and the stress at the time of formation. In the worst case, there is a risk of the base electrode and the collector electrode being electrically short-circuited by a contact between the base pad electrode and the collector electrode.

In addition, since the base pad structure itself serves as a shield and it is difficult to observe the side etching amount of the semiconductor layer immediately below by an electron microscope or the like in a non-destructive manner, it is also difficult to optimize the wet etching time.

### CITATION LIST

### Non Patent Literature

[NPL 1] Y. Shiratori et al., “High-Speed InP/InGaAsSb DHBT on High-Thermal-Conductivity SiC Substrate”, IEEE Electron Device Letters, vol. 39, No. 6, pp. 807-810, 2018.

### SUMMARY OF INVENTION

### Technical Problem

As described above, in the case of forming the InP-based HBT on the heat dissipation substrate to improve the heat dissipation, it is difficult to uniformly reduce the parasitic collector capacitance immediately below the base pad structure in the wafer surface, and there is a problem that the increase of the speed is limited.

The present invention has been made to solve the problem described above, and an object thereof is to enable the parasitic collector capacitance in the base pad structure to be reduced, without sacrificing the high speed characteristics.

### Solution to Problem

A hetero-junction bipolar transistor according to the present invention includes a collector electrode formed on a substrate in a smaller area than the substrate in a plan view; a sub-collector layer which is formed on the collector electrode in a smaller area than the collector electrode in a plan view and made of a compound semiconductor; a collector layer which is formed on the sub-collector layer and made of a compound semiconductor; a base layer which is formed on the collector layer and made of a compound semiconductor; an emitter layer which is formed on the base layer in an area smaller than that of the base layer in a plan view and made of a compound semiconductor; an emitter cap layer which is formed on the emitter layer and made of a compound semiconductor; an emitter electrode formed on the emitter cap layer; a base electrode which is formed on the base layer around the emitter layer; a collector post electrode formed on the collector electrode around the sub-collector layer; a base pad electrode which is connected to the base electrode and formed to extend outward from the base layer in a plan view; and a support portion which is formed on the substrate around the collector electrode apart from the collector electrode and supports an extension part of the base pad electrode on the collector electrode.

A method for manufacturing a hetero-junction bipolar transistor according to the present invention includes a first process of forming an emitter cap formation layer, an emitter formation layer, a base formation layer, a collector formation layer, and a sub-collector formation layer, each of which are made of a compound semiconductor, on a growth substrate made of the compound semiconductor by crystal growth in this order; a second process of forming a metal layer made of metal on the sub-collector formation layer; a third process of adhering a substrate onto the metal layer; a fourth process of removing the growth substrate after sticking the substrate onto the metal layer; a fifth process of forming a sub-collector layer, a collector layer, a base layer, an emitter layer having an area smaller than that of the base layer in a plan view, and an emitter cap layer on the metal layer, forming an emitter electrode on the emitter cap layer, and forming a base electrode on the base layer around the emitter layer, by patterning the sub-collector formation layer, the collector formation layer, the base formation layer, the emitter formation layer, and the emitter cap formation layer formed on the substrate via the metal layer; a sixth process of forming a collector post electrode and a first support portion on the metal layer around an element portion including the sub-collector layer, the collector layer, the base layer, the emitter layer, and the emitter cap layer; a seventh process of dividing the metal layer into a region in which the first support portion is formed, a region of the element portion, and a region of the first support portion to form a collector electrode disposed on the substrate under the element portion and a second support portion disposed on the substrate under the first support portion, and forming a support portion including the first support portion and the second support portion on the substrate around the collector electrode to be separated from the collector electrode; an eighth process of forming a protective layer which covers the element portion; a ninth process of exposing an upper part of the base electrode, an upper part of the collector post electrode, and an upper part of the support portion from the protective layer; and a tenth process of forming, on the protective layer, a base pad electrode which is formed on a side of the support portion, is connected to the base electrode exposed from the protective layer, and extends to an upper part of the support portion outside the base layer in a plan view.

### Advantageous Effects of Invention

As described above, according to the present invention, since the base pad electrode is formed to extend outward from the base layer in a plan view and the extension part of the base pad electrode is supported by the support portion, it is possible to reduce parasitic collector capacitance in the base pad structure without sacrificing high-speed characteristics.

### BRIEF DESCRIPTION OF DRAWINGS

FIG. 1 is a cross-sectional view showing the configuration of a hetero-junction bipolar transistor according to an embodiment of the present invention.

FIG. 2A is a cross-sectional view of a state of an element of a middle process for explaining a manufacturing method of a hetero-junction bipolar transistor according to an embodiment of the present invention.

FIG. 2B is a cross-sectional view of a state of an element of a middle process for explaining a manufacturing method of a hetero-junction bipolar transistor according to an embodiment of the present invention.

FIG. 2C is a cross-sectional view of a state of an element of a middle process for explaining a manufacturing method of a hetero-junction bipolar transistor according to an embodiment of the present invention.

FIG. 2D is a cross-sectional view of a state of an element of a middle process for explaining a manufacturing method of a hetero-junction bipolar transistor according to an embodiment of the present invention.

FIG. 2E is a cross-sectional view of a state of an element of a middle process for explaining a manufacturing method of a hetero-junction bipolar transistor according to an embodiment of the present invention.

FIG. 2F is a cross-sectional view of a state of an element of a middle process for explaining a manufacturing method of a hetero-junction bipolar transistor according to an embodiment of the present invention.

FIG. 2G is a cross-sectional view of a state of an element of a middle process for explaining a manufacturing method of a hetero-junction bipolar transistor according to an embodiment of the present invention.

FIG. 2H is a cross-sectional view of a state of an element of a middle process for explaining a manufacturing method of a hetero-junction bipolar transistor according to an embodiment of the present invention.

FIG. 2I is a cross-sectional view of a state of an element of a middle process for explaining a manufacturing method of a hetero-junction bipolar transistor according to an embodiment of the present invention.

FIG. 3 is a cross-sectional view of a configuration of a hetero-junction bipolar transistor of the related art.

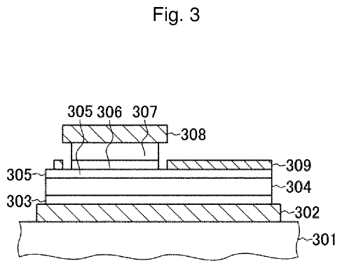

### DESCRIPTION OF EMBODIMENTS

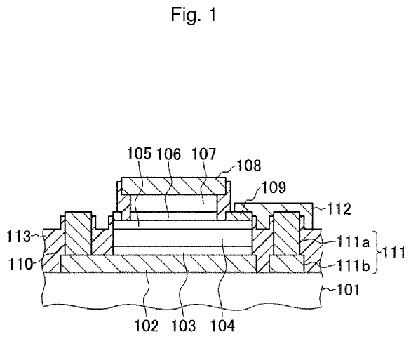

Hereinafter, a hetero-junction bipolar transistor according to an embodiment of the present invention will be described with reference to FIG. 1.

The hetero-junction bipolar transistor (HBT) includes a collector electrode 102 formed on a substrate 101 to have an area smaller than that of the substrate 101 in a plan view. In this technical field, the substrate 101 is made of a material used as a heat dissipation substrate. In this example, a collector electrode 102 is formed in contact with the top of the substrate 101.

For example, the substrate 101 is preferably made of a material having a thermal conductivity higher than that of InP and an insulating property equivalent to that of InP to facilitate an electrical isolation between elements. The substrate 101 can be made of, for example, Si, AIN, GaN, SiC, diamond, or a laminated structure in which these materials are combined. The collector electrode 102 is made of, for example, a metal made of Au/Ti or Au/Mo from the side of the substrate 101.

The HBT includes a sub-collector layer 103 which is formed on the collector electrode 102 in an area smaller than that of the collector electrode 102 in a plan view and made of a compound semiconductor, a collector layer 104 which is formed on the sub-collector layer 103 and made of a compound semiconductor, and a base layer 105 which is formed on the collector layer 104 and made of a compound semiconductor. In this example, the sub-collector layer 103 is formed in contact with the top of the collector electrode 102.

The sub-collector layer 103, the collector layer 104, and the base layer 105 are formed in the same area in a plan view, and they form a first mesa. The first Mesa has, for example, a columnar shape having a rectangular shape in a plan view. The sub-collector layer 103 is made of, for example, n⁺-InGaAs in which Si is doped with a high concentration to form an n-type. The collector layer 104 is made of, for example, InGaAs doped with Si at a low concentration to form an n-type. The base layer 105 is made of, for example, p⁺-GaAsSb in which C is doped with a high concentration to form a p-type.

The HBT includes an emitter layer 106 which is formed on the base layer 105 in a smaller area than the base layer 105 in a plan view and made of a compound semiconductor, and an emitter cap layer 107 which is formed on the emitter layer 106 and made of a compound semiconductor. The emitter layer 106 and the emitter cap layer 107 are formed to have the same area in a plan view, and they form a second mesa. The second Mesa is, for example, a columnar shape having a rectangular shape in a plan view. The second Mesa is disposed inside the first Mesa in a plan view.

For example, the emitter layer 106 is made of n-InP in which Si is doped at a low concentration to form an n-type. Also, the emitter cap layer 107 is made of n₊-InGaAs, which Si is doped at a high concentration to form an n-type.

The HBT includes an emitter electrode 108 formed on the emitter cap layer 107, and a base electrode 109 formed on the base layer 105 around the emitter layer 106. The emitter electrode 108 can be made of a metal such as Mo/W. The base electrode 109 can be made of a metal such as Au/Ti.

In addition to the above-described configuration, the HBT includes a support portion 111, a collector post electrode 110, and a base pad electrode 112.

The collector post electrode 110 is formed on the collector electrode 102 around the sub-collector layer 103. The base pad electrode 112 is electrically connected to the base electrode 109, and is formed to extend outward from the base layer 105 (the first Mesa) in a plan view. In this example, the second Mesa is disposed on the first Mesa with a larger area on the side of the support portion 111. The base electrode 109 also has a larger area on the side of the support portion 111. A base pad electrode 112 is connected to the base electrode 109 in the region having the larger area.

The support portion 111 is formed on the substrate 101 around the collector electrode 102 apart from the collector electrode 102. The support portion 111 supports an extension portion of the base pad electrode 112 on the collector electrode 102. In other words, the base pad electrode 112 is installed between the support portion 111 and the base electrode 109 formed on the side of the support portion 111. The support portion 111 is formed, for example, in a columnar shape.

In this example, the support portion 111 is constituted by a first support portion 111a and a second support portion 111b. The first support portion 111a is formed on the second support portion 111b. The support portion 111 (the first support portion 111a) is formed to be higher than the base electrode 109 with the surface of the substrate 101 as a reference. For example, the second support portion 111b can be made of the same material as the collector electrode 102. For example, when the collector electrode 102 is formed, the second support portion 111b can be formed at the same time. The first support portion 111a can be made of the same material as the collector post electrode 110. For example, when the collector post electrode 110 is formed, the first support portion 111a can be formed at the same time.

The HBT includes a protective layer 113 formed to cover an element portion including the collector electrode 102, the sub-collector layer 103, the collector layer 104, the base layer 105, the emitter layer 106, and the emitter cap layer 107. The protective layer 113 is made of, for example, a resin such as benzocyclobutene (BCB). The base pad electrode 112 is formed on the protective layer 113 around the element portion. The upper parts of the emitter electrode 108 and the base electrode 109 are exposed from the protective layer 113. The upper part of the collector post electrode 110 is exposed from the protective layer 113. The upper part of the support portion 111 (first support portion 111a) is exposed from the protective layer 113. The base pad electrode 112 is supported in contact with the exposed upper part of the support portion 111.

According to the embodiment, in principle, there is no semiconductor layer having a high relative dielectric constant immediately below the base pad electrode 112 extending outward from the base layer 105 (the first Mesa) in a plan view, in a region other than the base electrode 109. In this embodiment, the protective layer 113 having a lower relative dielectric constant than that of the semiconductor layer is formed in this region. As a result, the parasitic collector capacitance generated at the base pad electrode 112 can be reduced with high accuracy.

Further, by narrowing a width of a connecting portion between the base electrode 109 and the base pad electrode 112, the parasitic collector capacitance generated in the region of the connecting portion can be minimized. In this configuration, since it is not necessary to apply an undercut structure to the base layer 105, the collector layer 104, and the sub-collector layer 103 immediately under the connecting portion, the variation of parasitic collector capacitance can also be suppressed to the minimum.

In the embodiment, the support portion 111 is constituted of the first support portion 111a and the second support portion 111b. The second support portion 111b can be formed, for example, in the same process as the collector electrode 102. In the first support portion 111a, a collector post electrode 110 can be formed in the same process. As described above, according to the embodiment, the HBT according to the embodiment can be manufactured, only by adding the minimum number of processes to the conventional manufacturing processes of the HBT on the heat dissipation substrate. A height of the collector post electrode 110 and a height of the base pad electrode 112 can be made equal with each other with respect to the surface of the substrate 101.

Thus, the process of connecting an upper layer wiring and the base pad electrode 112 is also facilitated. For example, when the upper wiring is formed, an interlayer insulating film is formed after the element structure described using FIG. 1 is formed, the interlayer insulating film on the collector post electrode 110 and the base pad electrode 112 is removed, and a wiring metal is formed. At this time, if the height of the collector post electrode 110 and the base pad electrode 112 from the substrate 101 is substantially equal, the interlayer insulating film on the collector post electrode 110 and the base pad electrode 112 can be removed under the same condition, and the number of processes can be reduced.

Further, although secondarily, when the support portion 111 is made of metal, a path for dissipating the heat generated in the element to the substrate 101 via the base electrode 109, the base pad electrode 112 and the support portion 111 is newly formed, and the heat dissipation characteristics of the element formed on the substrate 101 can be further improved.

As described above, according to the present embodiment, the parasitic collector capacitance in the base pad structure can be reduced without sacrificing the high-speed characteristics (high-frequency characteristics). Further, according to the embodiment, the base pad structure can be formed uniformly in the wafer surface.

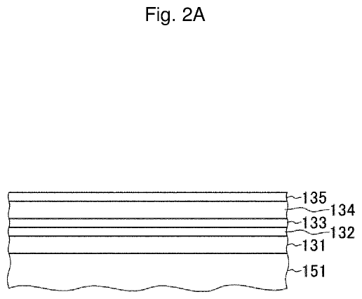

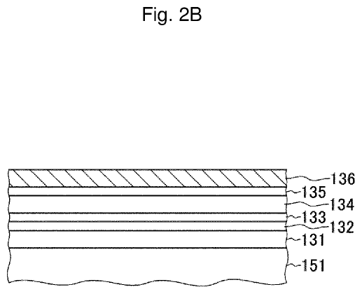

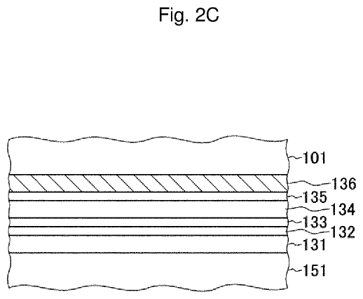

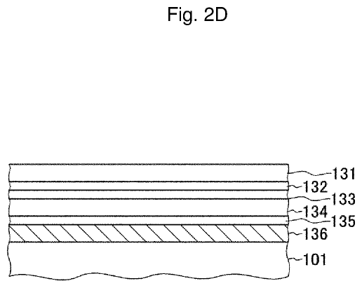

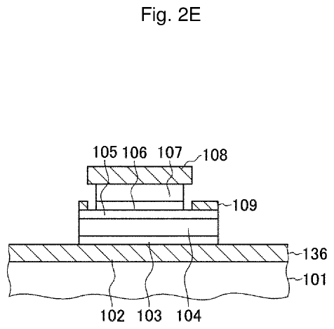

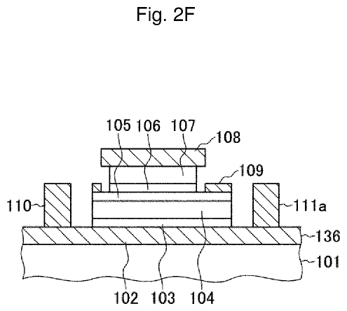

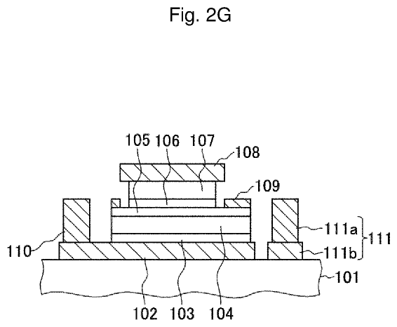

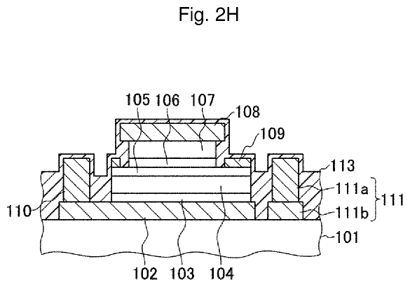

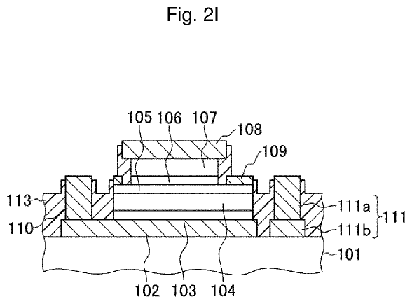

Next, a manufacturing method of a hetero-junction bipolar transistor according to an embodiment of the present invention will be described with reference to FIGS. 2A to 2I.

First, as shown in FIG. 2A, an emitter cap formation layer 131, an emitter formation layer 132, a base formation layer 133, a collector formation layer 134, and a sub-collector formation layer 135, which are respectively made of a compound semiconductor, are formed on a growth substrate 151 made of a compound semiconductor (made of InP), by a crystal growth in this order (a first process).

For example, the emitter cap formation layer 131 made of n₊-InGaAs, the emitter formation layer 132 made of n-InP, the base formation layer 133 made of p⁺-GaAsSb, the collector formation layer 134 made of n-InGaAs, and the sub-collector formation layer 135 made of n⁺-InGaAs is sequentially epitaxially grown on the growth substrate 151. The epitaxial growth of each layer can be performed by a known organometallic vapor phase growth method or molecular beam epitaxial growth method. Since each of the above-mentioned layers can be epitaxially grown on the growth substrate 151 made of InP in a lattice-matched state, good crystallinity with less dislocation and defects can be obtained.

Next, as shown in FIG. 2B, a metal layer 136 made of metal is formed on the sub-collector formation layer 135 (second process). For example, the metal layer 136 can be formed by depositing these metals, using vacuum deposition or sputtering as a composite structure of Ti/Au or Mo/Au from the side in contact with the sub-collector formation layer 135. When using Ti or Mo, good adhesion between the sub-collector formation layer 135 made of InGaAs and the metal layer 136 can be obtained. Thus, the HBT element formation layer is not peeled off from the substrate 101 due to heat and mechanical stress generated in an HBT element forming process to be described later. Since Au has a low Young's modulus and is not oxidized, it can be easily joined to a substrate 101 to be described later. The material of the metal layer 136 can be made of a material in which the sticking of the substrate 101 to be described later that can be bonded at a maximum allowable temperature or less of HBT.

Next, as shown in FIG. 2C, the substrate 101 is stuck on the metal layer 136 (third process). In the sticking, the metal layer 136 and the introduced metal layer are formed on the side of the substrate 101, and sticking (joining) between metal layers can be performed. As a method for sticking (joining), for example, known techniques such as a surface activated joining method and an atomic diffusion joining method can be used. In any joining technique, joining can be performed at a joining temperature of the maximum process temperature of the InP-based HBT (400 C) or lower. The removal of the growth substrate 151 can be performed, by utilizing known mechanical polishing or wet etching using a hydrochloric acid-based chemical.

As described above, after the substrate 101 is joined to the metal layer 136, the growth substrate 151 is removed (fourth process), and the surface of the emitter cap formation layer 131 is exposed as shown in FIG. 2D. As a result, the sub-collector formation layer 135, the collector formation layer 134, the base formation layer 133, the emitter formation layer 132, and the emitter cap formation layer 131 are formed on the substrate 101 via the metal layer 136.

Next, as shown in FIG. 2E, the sub-collector layer 103, the collector layer 104, the base layer 105, the emitter layer 106, the emitter cap layer 107, the emitter electrode 108, and the base electrode 109 are formed on the metal layer 136 (fifth process).

For example, a resist pattern having an opening at a position to be used as the emitter electrode 108 is formed on the emitter cap formation layer 131 by patterning using photolithography. Next, an emitter electrode material is deposited by a vacuum deposition. Thereafter, the resist pattern is lifted off to form an emitter electrode 108 on the emitter cap formation layer 131.

Next, the emitter formation layer 132 and the emitter cap formation layer 131 are patterned to form the emitter layer 106. The emitter layer 106 and the emitter cap layer 107 are formed in the same area in a plan view to form a second Mesa.

The emitter cap layer 107 and the emitter layer 106 can be formed, by etching the emitter cap formation layer 131 and the emitter formation layer 132 with a citric acid-based etchant and a hydrochloric acid-based etchant, respectively, using the emitter electrode 108 as a mask. The citric acid-based etchant hardly etches the emitter formation layer 132 made of InP. The hydrochloric acid etchant hardly etches the emitter cap layer 107 made of InGaAs and the base formation layer 133 made of GaAsSb. Therefore, the emitter cap layer 107 and the emitter layer 106 can be individually formed, using the etchant.

Next, the base electrode 109 is formed on the base formation layer 133 (base layer 105) around the emitter layer 106. The base electrode 109 can be formed by the same manufacturing method (lift-off method) as that of the emitter electrode 108. One of the base electrodes 109 formed on both sides of the emitter layer 106 is formed to be slightly wider than the other, and is used as a connecting portion of the base pad electrode 112. This is to provide a margin for alignment accuracy when forming the base pad electrode 112, which will be described later. However, since the parasitic collector capacitance increases when the area of the region for this connection increases, it is desirable to reduce the area of the region in terms of high frequency characteristics, as far as it can be connected to the base pad electrode 112 with a high yield.

Then, the sub-collector formation layer 135, the collector formation layer 134, and the base formation layer 133 are patterned to form the sub-collector layer 103, the collector layer 104 and the base layer 105. The base layer 105 is formed so that the emitter layer 106 and the emitter cap layer 107 have areas smaller than those of the base layer 105 in a plan view. The sub-collector layer 103, the collector layer 104 and the base layer 105 are formed in the same area in a plan view to form a first Mesa.

The base layer 105, the collector layer 104, and the sub-collector layer 103 can be formed, by etching the base formation layer 133, the collector formation layer 134, and the sub-collector formation layer 135 with a citric acid-based etchant, a hydrochloric acid-based etchant, and a citric acid-based etchant, respectively, using a resist mask patterned in the same manner as the emitter electrode 108.

Next, as shown in FIG. 2F, a collector post electrode 110 and a first support portion 111a are formed on the metal layer 136 around an element part provided with the sub-collector layer 103, the collector layer 104, the base layer 105, the emitter layer 106 and the emitter cap layer 107 (a sixth process). For example, the collector post electrode 110 and the first support portion 111a can be formed by the lift-off method. By forming the collector post electrode 110 and the first support portion 111a having a proper thickness (height), connection with the upper-layer wiring can be facilitated. It is desirable that the thickness be at least thicker than the total of the sub-collector layer 103, the collector layer 104 and the base layer 105. The first support portion 111a is formed to be equal to or higher than the base electrode 109 with the surface of the substrate 101 as a reference.

Next, the metal layer 136 is separated into a region in which the first support portion 111a is formed, a region of the element part, and a region of the first support portion 111a, and a collector electrode 102 and a second support portion 111b are formed (seventh process), as shown in FIG. 2G. The second support portion 111b is formed on the substrate 101 around the collector electrode 102 apart from the collector electrode 102. The collector electrode 102 and the second support portion 111b can be formed, by patterning the metal layer 136 by etching treatment using a predetermined resist pattern as a mask. For example, metals such as Ti and Mo can be etched by fluorine-based dry etching. The Au can be etched by wet etching using an iodine-based chemical solution or ion milling using an AR-based gas.

The collector electrode 102 is disposed on the substrate 101 under the element part. The second support portion 111b is disposed on the substrate 101 under the first support portion 111a. The support portion 111 is constituted of the first support portion 111a and the second support portion 111b. Further, a support portion 111 is formed on the substrate 101 around the collector electrode 102 apart from the collector electrode 102.

Next, as shown in FIG. 2H, the protective layer 113 that covers the element part is formed (eighth process). For example, the protective layer 113 can be formed by spin-coating BCB to form a coating film and heating the coating film at a high temperature to cure the coating film. The viscosity of the BCB and the spin coat rotation number are adjusted such that a design thickness of the protective layer 113 in this stage is thinner than the total thickness of the collector electrode 102, the sub-collector layer 103, the collector layer 104, and the base layer 105. Thus, the protective layer 113 having a design thickness is formed on the substrate 101 on which the element part is not formed, and on the other hand, the protective layer 113 is formed in a very thin state on a region higher than the design thickness, (specifically, on the emitter electrode 108, the base electrode 109, the support portion 111 and the collector post electrode 110).

Next, as shown in FIG. 21, the upper part of the base electrode 109, the upper part of the collector post electrode 110, and the upper part of the support portion 111 are exposed from the protective layer 113 (ninth process). For example, by etching back the entire region (entire surface) of the protective layer 113, the upper part of the base electrode 109, the upper part of the collector post electrode 110, and the upper part of the support portion 111 can be exposed from the protective layer 113. When the protective layer 113 is formed, only the upper part of the base electrode 109, the upper part of the collector post electrode 110, and the upper part of the support portion 111 can be exposed, by forming the protective layer 113 to an appropriate thickness.

Next, a base pad electrode 112, which is formed on the side of the support portion 111 and connected to the base electrode 109 exposed from the protective layer 113 and extends to the upper part of the support portion 111 on the outside of the base layer 105 in a plan view, is formed on the protective layer 113 (tenth process). As a result, the hetero-junction bipolar transistor described using FIG. 1 can be obtained. The base pad electrode 112 can be formed by the aforementioned lift-off method.

As described above, according to the present invention, since the base pad electrode is formed to extend outward from the base layer in a plan view and the extension part of the base pad electrode is supported by the support portion, the base pad electrode is installed between the support portion and the base electrode, and the parasitic collector capacitance in the base pad structure can be reduced, without sacrificing the high speed characteristics.

Also, it is apparent that the present invention is not limited to the embodiment described above, and many modifications and combinations can be performed by those having ordinary knowledge in the art within the technical idea of the present invention. For example, although an npn-type InP/GaAsSb-based HBT on a heat dissipation substrate that is promising in terms of realizing a very high-speed integrated circuit is described in detail in the above, a similar effect is also valid for other HBTs.

### REFERENCE SIGNS LIST

101 Substrate
102 Collector electrode
103 Sub-collector layer
104 Collector layer
105 Base layer
106 Emitter layer
107 Emitter cap layer
108 Emitter electrode
109 Base electrode
110 Collector post electrode
111 Support portion
111a First support portion
111b Second support portion
112 Base pad electrode
113 Protective pad

1. A hetero-junction bipolar transistor comprising:
a collector electrode formed on a substrate in a smaller area than the substrate in a plan view;
a sub-collector layer formed on the collector electrode in a smaller area than the collector electrode in a plan view and made of a compound semiconductor;
a collector layer which is formed on the sub-collector layer and made of a compound semiconductor;
a base layer which is formed on the collector layer and made of the compound semiconductor;
an emitter layer which is formed on the base layer in an area smaller than that of the base layer in a plan view and made of the compound semiconductor;
an emitter cap layer which is formed on the emitter layer and made of the compound semiconductor;
an emitter electrode formed on the emitter cap layer;
a base electrode which is formed on the base layer around the emitter layer;
a collector post electrode formed on the collector electrode around the sub-collector layer;
a base pad electrode which is connected to the base electrode and formed to extend outward from the base layer in a plan view; and
a support portion which is formed on the substrate around the collector electrode apart from the collector electrode and supports an extension part of the base pad electrode on the collector electrode.

2. The hetero-junction bipolar transistor according to claim 1, further comprising:
a protective layer formed to cover an element portion including the collector electrode, the sub-collector layer, the collector layer, the base layer, the emitter layer, and the emitter cap layer, and
the base pad electrode is formed on the protective layer around the element portion.

3. The hetero-junction bipolar transistor according to claim 1,
wherein the support portion is formed to be equal to or higher than the base electrode with respect to a surface of the substrate.

4. A method for manufacturing a hetero-junction bipolar transistor, the method comprising:
a first process of forming an emitter cap formation layer, an emitter formation layer, a base formation layer, a collector formation layer, and a sub-collector formation layer, each of which are made of a compound semiconductor, on the growth substrate made of the compound semiconductor by a crystal-growth in this order;
a second process of forming a metal layer made of metal on the sub-collector formation layer;
a third process of sticking a substrate onto the metal layer;
a fourth process of removing the growth substrate after sticking the substrate onto the metal layer;
a fifth process of forming a sub-collector layer, a collector layer, a base layer, an emitter layer having an area smaller than that of the base layer in a plan view, and an emitter cap layer on the metal layer, forming an emitter electrode on the emitter cap layer, and forming a base electrode on the base layer around the emitter layer, by patterning the sub-collector formation layer, the collector formation layer, the base formation layer, the emitter formation layer, and the emitter cap formation layer formed on the substrate via the metal layer;
a sixth process of forming a collector post electrode and a first support portion on the metal layer around an element portion including the sub-collector layer, the collector layer, the base layer, the emitter layer, and the emitter cap layer;
a seventh process of dividing the metal layer into a region in which the first support portion is formed, a region of the element portion, and a region of the first support portion to form a collector electrode disposed on the substrate under the element portion and a second support portion disposed on the substrate under the first support portion, and forming a support portion including the first support portion and the second support portion on the substrate around the collector electrode to be separated from the collector electrode;
an eighth process of forming a protective layer which covers the element portion;
a ninth process of exposing an upper part of the base electrode, an upper part of the collector post electrode, and an upper part of the support portion from the protective layer; and
a tenth process of forming, on the protective layer, a base pad electrode which is formed on a side of the support portion, is connected to the base electrode exposed from the protective layer, and extends to an upper part of the support portion outside the base layer in a plan view.

5. The method for manufacturing the hetero-junction bipolar transistor according to claim 4,
wherein the sixth process forms the first support portion to be equal to or higher than the base electrode with reference to a surface of the substrate.

6. The hetero-junction bipolar transistor according to claim 2,
wherein the support portion is formed to be equal to or higher than the base electrode with respect to a surface of the substrate.
